(19) United States
(12) Patent Application Publication
(10) Pub. No.: US 2025/0151311 A1
(43) Pub. Date: May 8, 2025

(54) SEMICONDUCTOR DEVICE

(71) Applicant: XIAMEN SAN'AN INTEGRATED CIRCUIT CO., LTD., Xiamen (CN)

(72) Inventors: Wangping WANG, Xiamen (CN); Jiebin ZHONG, Xiamen (CN); Yuxiang YOU, Xiamen (CN)

(21) Appl. No.: 18/745,689

(22) Filed: Jun. 17, 2024

Related U.S. Application Data
(63) Continuation-in-part of application No. PCT/CN2023/129606, filed on Nov. 3, 2023.

(51) Int. Cl. H01L 29/778; H01L 21/02; H01L 21/285; H01L 21/311; H01L 23/31; H01L 29/20; H01L 29/423; H01L 29/66

(52) U.S. Cl. CPC H10D 30/475; H01L 21/02126; H01L 21/0217; H01L 21/28581; H01L 21/31138; H01L 23/3171; H10D 30/015; H10D 64/411; H10D 62/8503

(57) ABSTRACT

A semiconductor device includes an epitaxial structure, a source electrode, a drain electrode, a gate electrode, and a passivation structure. The source electrode and the drain electrode are disposed on the epitaxial structure and spaced apart from each other. The gate electrode is disposed on the epitaxial structure and between the source electrode and the drain electrode, and has a foot portion and a head portion. The passivation structure is disposed on the epitaxial structure and includes a first passivation layer, a first detective dielectric layer, and a first interlayer dielectric layer. The first detective dielectric layer includes an element that is different from elements contained in the first interlayer dielectric layer. The first passivation layer, the first detective dielectric layer and the first interlayer dielectric layer are disposed adjacent to a side surface of the foot portion of the gate electrode.

### CROSS-REFERENCE TO RELATED APPLICATION

This application is a continuation-in-part (CIP) of International Application No. PCT/CN2023/129606, filed on Nov. 3, 2023, the entire disclosure of which is incorporated by reference herein.

### FIELD

The disclosure relates to a semiconductor device.

### BACKGROUND

A conventional high electron mobility transistor (HEMT) device, such as a GaN HEMT device, utilizes strong piezoelectricity of the heterojunction (e.g., an AlGaN/GaN heterojunction) to generate the two-dimensional electron gas (2DEG) that has properties of high mobility and high density, which is adapted for processing and transmitting signals with high power and high frequency. A GaN HEMT device usually has issues such as current collapse and defects in surface. Currently, surface passivation technique is commonly used in manufacturing of the GaN HEMT devices to enhance the abilities of the GaN HEMT devices to avoid ionic contamination, and effectively suppress current collapse resulting from surface states. In addition, virtual gate effects caused by air ionization can be effectively controlled using surface passivation, thereby suppressing current collapse and enhancing performance of the GaN HEMT devices. In the manufacturing process of HEMT devices, surface passivation is to deposit passivation layers on the epitaxial structure, and to form the gate recess in the passivation layers using dry-etch with a higher etching selectivity to the passivation layers than to the photoresist. As the need of the HEMT devices with high frequency grows, further narrowing the gate length (i.e., a size of the gate electrode in a direction from the source electrode to the drain electrode) is necessary. However, in the etching process of passivation layers of the HEMT device, due to the narrowed gate length, it is relatively difficult to etch the passivation layers, which adversely affects the consistency of the gate recess in mass production of the HEMT devices.

In a conventional GaN HEMT device, the source electrode, the drain electrode and the gate electrode are disposed on the group III-V epitaxial structure, and the group III-V epitaxial structure is protected by disposing a plurality of passivation layers having different materials thereon. Since materials and stresses of the passivation layers are different, additional stresses are introduced, thereby decreasing performance of the HEMT device. In other situations, the GaN HEMT device may have only one passivation layer to protect the group III-V epitaxial structure. A commonly-used method of depositing the passivation layer(s) that is (are) made of a SiN material on the epitaxial structure will introduce additional parasitic capacitance, which results in frequency characteristics of the HEMT devices going down and adversely affects the HEMT devices in being applied in the high frequency products. Thus, there is room for improvement.

### SUMMARY

Therefore, an object of the disclosure is to provide a semiconductor device that can alleviate at least one of the drawbacks of the prior art.

According to one aspect of the disclosure, the semiconductor device includes an epitaxial structure, a source electrode, a drain electrode, a gate electrode, and a passivation structure. The epitaxial structure has a group-III nitride material, and includes a channel layer and a barrier layer that is disposed on the channel layer. The source electrode is disposed on the epitaxial structure, and the drain electrode is disposed on the epitaxial structure and spaced apart from the source electrode. The gate electrode is disposed on the epitaxial structure and between the source electrode and the drain electrode, and has a foot portion and a head portion. The passivation structure is disposed on the epitaxial structure and includes a first passivation layer that is disposed on the epitaxial structure, a first detective dielectric layer that is disposed on the first passivation layer, and a first interlayer dielectric layer that is disposed on the first detective dielectric layer. The first detective dielectric layer includes an element that is different from elements contained in the first interlayer dielectric layer. A ratio of a thickness of the first detective dielectric layer to a thickness of the first passivation layer is smaller than 1:10. A ratio of the thickness of the first detective dielectric layer to a thickness of the first interlayer dielectric layer is smaller than 1:50. A thickness of the passivation structure ranges from 500 Å to 5000 Å. The first passivation layer, the first detective dielectric layer and the first interlayer dielectric layer are disposed adjacent to a side surface of the foot portion of the gate electrode.

According to another aspect of the disclosure, the semiconductor device includes an epitaxial structure, a source electrode, a drain electrode, a gate electrode, and a passivation structure. The epitaxial structure has a group-III nitride material, and includes a channel layer and a barrier layer that is disposed on the channel layer. The source electrode is disposed on the epitaxial structure, and the drain electrode is disposed on the epitaxial structure and spaced apart from the source electrode. The gate electrode is disposed on the epitaxial structure and between the source electrode and the drain electrode, and has a foot portion and a head portion. The passivation structure is disposed on the epitaxial structure and includes a first passivation layer that is disposed on the epitaxial structure, a first detective dielectric layer that is disposed on the first passivation layer, a first interlayer dielectric layer that is disposed on the first detective dielectric layer, a second detective dielectric layer that is disposed on the first interlayer dielectric layer, and a second interlayer dielectric layer that is disposed on the second detective dielectric layer. The first detective dielectric layer includes an element that is different from elements contained in the first interlayer dielectric layer. The second detective dielectric layer includes an element that is different from elements contained in the second interlayer dielectric layer. Each of the first detective dielectric layer and the second detective dielectric layer is composed of silicon, oxygen and nitrogen, is composed of silicon and oxygen, or is composed of aluminum and nitrogen. A thickness of the first detective dielectric layer ranges from 0.5 Å to 15 Å, and a thickness of the second detective dielectric layer ranges from 0.5 Å to 15 Å. The first passivation layer, the first detective dielectric layer, the first interlayer dielectric layer, the second detective dielectric layer and the second interlayer dielectric layer are disposed adjacent to a side surface of the foot portion and between the head portion and the epitaxial structure.

According to yet another aspect of the disclosure, the semiconductor device includes an epitaxial structure and a passivation structure. The passivation structure is disposed on the epitaxial structure and includes a first passivation layer that is disposed on the epitaxial structure, a first detective dielectric layer that is disposed on the first passivation layer, a first interlayer dielectric layer that is disposed on the first detective dielectric layer, a second detective dielectric layer that is disposed on the first interlayer dielectric layer, and a second interlayer dielectric layer that is disposed on the second detective dielectric layer. A ratio of a thickness of the first detective dielectric layer to a thickness of the first passivation layer is smaller than 1:10. A ratio of the thickness of the first detective dielectric layer to a thickness of the first interlayer dielectric layer is smaller than 1:10. A ratio of a thickness of the second detective dielectric layer to the thickness of the first interlayer dielectric layer is smaller than 1:10. A ratio of the thickness of the second detective dielectric layer to a thickness of the second interlayer dielectric layer is smaller than 1:50. The first detective dielectric layer includes an element that is different from elements contained in the first interlayer dielectric layer. The second detective dielectric layer includes an element that is different from elements contained in the second interlayer dielectric layer. The first passivation layer, the first detective dielectric layer, the first interlayer dielectric layer, the second detective dielectric layer and the second interlayer dielectric layer include the same two elements. The thickness of the first passivation layer ranges from 30 Å to 200 Å. A thickness of the passivation structure ranges from 500 Å to 5000 Å. The thickness of the first detective dielectric layer ranges from 0.5 Å to 15 Å. The thickness of the second detective dielectric layer ranges from 0.5 Å to 15 Å.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating portions of a passivation structure and an epitaxial structure used for forming a first embodiment of a semiconductor device according to the disclosure.

FIG. 2 is a view similar to FIG. 1, but having a gate recess.

FIG. 3 is a schematic view of the first embodiment of the semiconductor device according to the disclosure.

FIG. 4 is a schematic view illustrating a portion of a second embodiment of the semiconductor device according the disclosure.

FIG. 5 is a schematic view illustrating portions of the passivation structure and the epitaxial structure used for forming a third embodiment of the semiconductor device according to the disclosure.

FIG. 6 is view similar to FIG. 5, but having the gate recess.

FIG. 7 is a schematic view of a portion of the third embodiment of the semiconductor device according to the disclosure.

FIG. 8 is an enlarged schematic view of Section A in FIG. 7.

FIG. 9 is a schematic view of a portion of a fourth embodiment of the semiconductor device according to the disclosure.

FIG. 10 is an enlarged schematic view of Section B in FIG. 9.

FIG. 11 is a schematic view of a portion of a fifth embodiment of the semiconductor device according to the disclosure.

FIG. 12 is a view of a variation of the fifth embodiment.

FIG. 13 is a schematic view of a portion of a sixth embodiment of the semiconductor device according to the disclosure.

FIG. 14 is a view of a variation of the sixth embodiment.

FIG. 15 is a view similar to FIG. 7, but illustrating a gate electrode that is inverted-L shaped.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

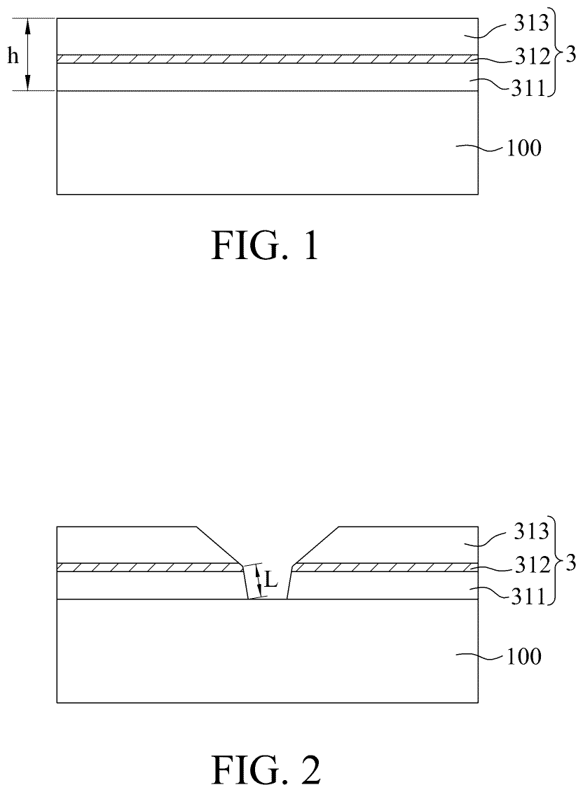

FIGS. 1 to 3 illustrate three intermediate stages for forming a first embodiment of a semiconductor device according to the disclosure, respectively. In the first embodiment, the semiconductor device includes an epitaxial structure 100, a source electrode(S), a drain electrode (D), a gate electrode 200 having a foot portion 210 and a head portion 220, and a passivation structure 3. The passivation structure 3 is disposed on the epitaxial structure 100 for protecting a surface of the epitaxial structure 100 and increasing a breakdown voltage of the semiconductor device. The passivation structure 3 includes a first passivation layer 311 that is disposed on the epitaxial structure 100, a first detective dielectric layer 312 that is disposed on the first passivation layer 311, and a first interlayer dielectric layer 313 that is disposed on the first detective dielectric layer 312, and the first detective dielectric layer 312 has a thickness ranging from 0.5 Å to 15 Å. The first detective dielectric layer 312 includes an element that is different from elements contained in the first interlayer dielectric layer 313; that is, the first detective dielectric layer 312 includes an element that the first interlayer dielectric layer 313 does not have.

For the layers of the passivation structure 3 having good lattice matching characteristics therebetween, the first detective dielectric layer 312 includes an element that is the same as one of the elements contained in the first interlayer dielectric layer 313, and/or the same as one of elements contained in the first passivation layer 311.

Further, in order to enhance the capability of detecting an etching endpoint (i.e., on that point, the etching will be stopped), the first detective dielectric layer 312 includes an element that is different from the elements contained in the first interlayer dielectric layer 313, and/or different from the elements contained in the first passivation layer 311.

The first detective dielectric layer 312 is composed of nitrogen, silicon and oxygen, or is composed of silicon and oxygen, or is composed of aluminum and nitrogen. The passivation layer 3 has a thickness (h) ranging from 500 Å to 5000 Å. The first passivation layer 311 has a thickness ranging from 30 Å to 200 Å. A ratio of the thickness of the first detective dielectric layer 312 to the thickness of the first passivation layer 311 is smaller than 1:10. The thickness of the first detective dielectric layer 312 cannot be too large; otherwise, an additional stress from the first detective dielectric layer 312 will be introduced to the passivation structure 3, which makes a combined stress of the passivation structure 3 to change from a two-layered combination to a three-layered combination, thereby increasing the difficulty in optimizing a stress of the semiconductor device. That is, when the thickness of the first detective dielectric layer 312 is small enough, the stress thereof can be omitted. In some embodiments, a ratio of the thickness of the first detective dielectric layer 312 to a thickness of the first interlayer dielectric layer 313 is smaller than 1:50. In some embodiments, the thickness of the first interlayer dielectric layer 313 is greater than the thickness of the first detective dielectric layer 312. After some experiments, it is found that when the ratio of the thickness of the first detective dielectric layer 312 to the thickness of the first passivation layer 311 is smaller than 1:10, effects of the stress of the first detective dielectric layer 312 on the combined stress of the passivation structure 3 and effects of the first detective dielectric layer 312 on the gate electric field can be omitted, and the capability of detecting an etching endpoint can be enhanced, which is beneficial to optimizing a topography of a gate recess of the semiconductor device. The first interlayer dielectric layer 313 is mainly used to modulate the electric field strength under the gate electrode 200 of the semiconductor device and the gate parasitic capacitance of the semiconductor device. From a perspective of gate parasitic capacitance optimization, the thickness of the first interlayer dielectric layer 313 should be as large as possible. However, the larger the thickness of the first interlayer dielectric layer 313, the weaker the electric field modulating capability of the metal gate field plate formed on the head portion 220 of the gate electrode 200. In some embodiments, a ratio of the thickness of the first passivation layer 311 to the thickness of the first interlayer dielectric layer 313 is smaller than 1:5. When the ratio of the thickness of the first passivation layer 311 to the thickness of the first interlayer dielectric layer 313 is smaller than 1:20, performance of the semiconductor device becomes poor. Therefore, in this embodiment, the ratio of the thickness of the first passivation layer 311 to the thickness of the first interlayer dielectric layer 313 ranges from 1:20 to 1:5.

In some embodiments, the first passivation layer 311 and the first interlayer dielectric layer 313 include the same two elements; that is, the first passivation layer 311 includes two elements that are the same as two of the elements contained in the first interlayer dielectric layer 313. In some embodiments, considering the modulating capability of the metal gate field plate and gate parasitic capacitance optimization, the passivation structure 3 has a thickness (h) of 1000 Å, and the first detective dielectric layer 312 is included in the passivation structure 3, such that stress relief of the passivation structure 3 during the manufacturing process of the semiconductor device is improved.

The epitaxial structure 100 has a group-III nitride material. Specifically, the epitaxial structure 100 includes a group III-V compound, such as gallium nitride (GaN), aluminum gallium nitride (AlGaN), gallium arsenide (GaAs), and so on, and in this embodiment, the semiconductor device is exemplified as a GaN high electron mobility transistor (HEMT). In this case, the epitaxial structure 100 that is a GaN-based epitaxial structure includes a buffer layer having a GaN material, a channel layer having a GaN material, a barrier layer having an AlGaN material, and a capping layer having a GaN material. The barrier layer is disposed on the channel layer, and a layer of the two-dimensional electron gas (2DEG) is disposed between the channel layer and the barrier layer.

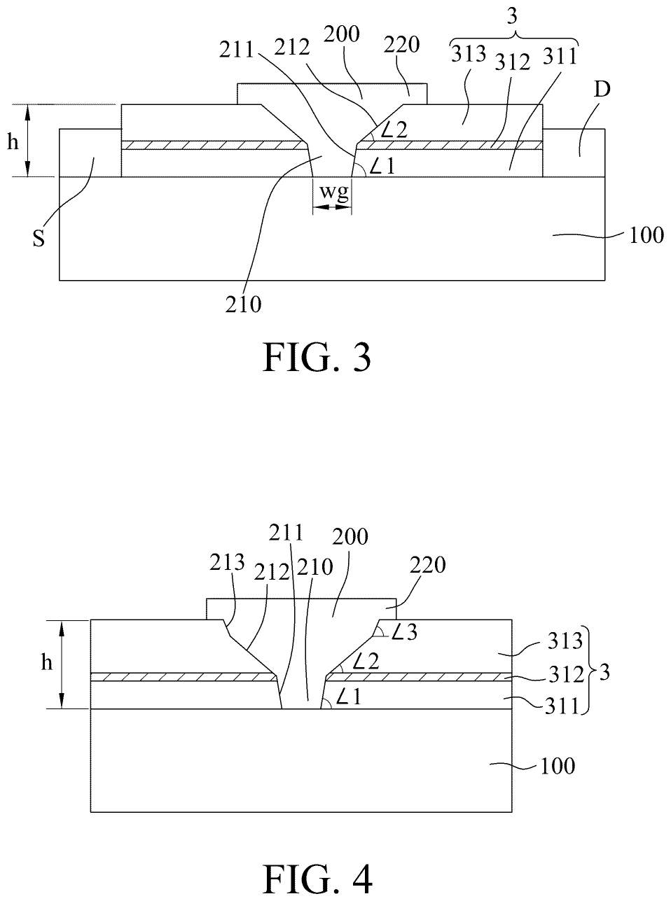

Referring to FIG. 3, in the first embodiment, the source electrode (S) and the drain electrode (D) are disposed on the epitaxial structure 100 and spaced apart from each other, and the gate electrode 200 is disposed on the epitaxial structure 100 and between the source electrode(S) and the drain electrode (D). The first passivation layer 311, the first detective dielectric layer 312 and the first interlayer dielectric layer 313 of the passivation structure 3 are disposed adjacent to a side surface of the foot portion 210 of the gate electrode 200 and between the head portion 220 and the epitaxial structure 100.

The first passivation layer 311 is deposited on the epitaxial structure 100 using plasma-enhanced chemical vapor deposition (PECVD). The first passivation layer 311 includes or is made of silicon nitride, and has the thickness of 80 Å. The first detective dielectric layer 312 is deposited on the first passivation layer 311 using atomic layer deposition (ALD). In some embodiments, the first detective dielectric layer 312 includes or is made of aluminum nitride, and has the thickness ranging from 0.5 Å to 15 Å, or from 2 Å to 5 Å. In this embodiment, the thickness of the first detective dielectric layer 312 is exemplified as 5 Å. The first interlayer dielectric layer 313 is deposited on the first detective dielectric layer 312 using PECVD. The first interlayer dielectric layer 313 includes or is made of silicon nitride, and has the thickness of 1000 Å. In this case, the thickness of the passivation structure 3 is 1085 Å.

By virtue of the multi-layered structure of the passivation structure 3 in this embodiment, combination of the first passivation layer 311 and the first passivation layer 311 may effectively modulate the combined stress, and the electric field and the parasitic capacitance of the semiconductor device are improved through the specific thickness ranges of the first passivation layer 311, the first detective dielectric layer 312 and the first interlayer dielectric layer 313.

Referring to FIG. 3, the passivation structure 3 has a side wall that is adjacent to the side surface of the foot portion 210 (i.e., the side wall of the passivation structure 3 faces the side surface of the foot portion 210) and that has two wall portions 211, 212 inclined with respect to an imaginary plane parallel to the epitaxial structure 100 by different angles. A junction of the wall portions 211, 212 is at a portion of the side wall that is adjacent to the first detective dielectric layer 312 (i.e., the wall portion 211 is adjacent to the first passivation layer 311 and the wall portion 212 is adjacent to the first interlayer dielectric layer 313).

A method for preparing the semiconductor device is as follows. The epitaxial structure 100 having a heterojunction is formed on a SiC substrate (not shown in the drawings). The source electrode(S) and the drain electrode (D) are formed on an active region of the epitaxial structure 100 opposite to the SiC substrate, and are spaced apart from each other. The epitaxial structure 100 includes the channel layer and the barrier layer that is disposed on the channel layer. The channel layer is a binary group III-V compound semiconductor layer made of a group III-nitride material, and the barrier layer is a ternary group III-V compound semiconductor layer made of a group III-nitride material. For the passivation structure 3, the first passivation layer 311, the first detective dielectric layer 312 and the first interlayer dielectric layer 313 are sequentially formed on the epitaxial structure 100. During the etching process for the passivation structure 3, an etching method for the first interlayer dielectric layer 313 (e.g., a dry etching method) is performed when a first element and a second element (such as silicon and nitrogen) are detected in the passivation structure 3, and an etching method for the first passivation layer 311 (e.g., a dry etching method) is performed when a third element (such as aluminum) in the first detective dielectric layer 312 is detected in the passivation structure 3. The etching process of the passivation structure 3 ends when a portion of the epitaxial structure 100 is exposed for disposing the gate electrode 200. That is, since the first detective dielectric layer 312 includes an element (i.e., the third element) that is different from the elements contained in the first interlayer dielectric layer 313, when the different element (i.e., the third element) is detected during the etching process of the passivation structure 3, it is acquired that a portion of the first detective dielectric layer 312 is exposed, and therefore the etching method is changed to another one for etching other layers of the passivation structure 3. After the etching process of the passivation structure 3 ends (i.e., the portion of the epitaxial structure 100 is exposed), Schottky metal is deposited on the portion of the epitaxial structure 100 that is exposed to form the gate electrode 200. By virtue of the first detective dielectric layer 312, change of the etching methods can be effectively controlled and the capability of detecting the etching endpoint is optimized, and thus the etching of the passivation structure 3 can be repeatedly performed in mass production of the semiconductor devices, which avoids differences in performance of the semiconductor devices.

In some embodiments, the source electrode(S) and the drain electrode (D) are formed on the barrier layer at the active region, and the passivation structure 3 is formed among the source electrode(S), the drain electrode (D) and the gate electrode 200.

Before the etching of the passivation structure 3, a portion of the passivation structure 3 that is to be etched (i.e., the portion corresponds in position to the portion of the epitaxial structure 100 that is to be exposed for disposing the gate electrode 200) is exposed from a patterned mask using photolithography. In this embodiment, the first passivation layer 311 and the first interlayer dielectric layer 313 are made of a SiN material, and the first detective dielectric layer 312 is made of an AlN material. The first interlayer dielectric layer 313 exposed from the patterned mask is etched until aluminum in the first detective dielectric layer 312 is detected, and the wall portion 212 is formed (in this case, the first detective dielectric layer 312 serves as an etch stop layer). In some cases, a portion of the first detective dielectric layer 312 exposed from the patterned mask is completely removed to expose the first passivation layer 311 by wet-etching that has a high etching selectivity to the first detective dielectric layer 312 or by dry-etching that is suitable for etching the first detective dielectric layer 312. Alternatively, since the thickness of the first detective dielectric layer 312 is relatively small (e.g., a few nanometers), the portion of the first detective dielectric layer 312 may be naturally removed by the dry-etching method for the first passivation layer 311 without a specific etching method. Then, a portion of the first passivation layer 311 exposed from the patterned mask is etched and removed and the portion of the epitaxial structure 100 is exposed, and the wall portion 211 is formed. As shown in FIG. 2, the wall portion 211 is inclined with respect to the imaginary plane by the angle (∠1) ranging from 70° to 90°, and the wall portion 212 is inclined with respect to the imaginary plane by the angle (∠2) ranging from 30° to 60°. A gate metal material (e.g., Schottky metal) is deposited on the portion of the epitaxial structure 100 that is exposed to form the gate electrode 200 (see FIG. 3). The passivation structure 3 is disposed adjacent to the foot portion 210 and between the head portion 220 and the epitaxial structure 100, and the head portion 220 abuts against an upper surface of the first interlayer dielectric layer 313.

From a perspective of the radio frequency (RF) response angle of the semiconductor device, the greater the angle (∠1), the smaller the parasitic capacitance in the active region, thereby enhancing the RF of the semiconductor device.

Furthermore, the angle (∠2) is smaller than the angle (∠1), and a difference of the two angles (∠1,∠2) is not smaller than 10° and is not greater than 60°, which is beneficial to coverage of the gate electrode 200 in the gate recess and enhances reliability of the semiconductor device.

As the need of the semiconductor devices (e.g., the GaN HEMT) with high frequency range grows, narrowing the gate length is necessary and requirements of the gate dielectric are higher. In some embodiments, the gate electrode 200 has a gate length (Wg) (i.e., a size of the foot portion 210 along a direction from the source electrode(S) to the drain electrode (D)) that ranges from 500 Å to 7000 Å, and that is greater than the thickness (h) of the passivation structure 3 (please note that the drawings are for illustration only but not drawn to scale). Thus, the coverage of the gate electrode 200 on the passivation structure 3 is relatively stable. The capability of detecting the etching endpoint during the etching process of the passivation structure 3 is enhanced by the detection of the third element in the first detective dielectric layer 312, which is beneficial to a consistency of a topography of the wall portion 211 in mass production of the semiconductor devices. That is, since the capability of detecting the etching endpoint is enhanced, the gate length (Wg) can be controlled, and a length (L) of the wall portion 211 along a direction that is substantially perpendicular to the imaginary plane is controlled. The length (L) is smaller than 200 Å. Therefore, a consistency of the gate electrode 200 is controlled in mass production of the semiconductor devices, especially a consistency of the foot portion 210 of the gate electrode 200.

In some embodiments, the first passivation layer 311, the first detective dielectric layer 312, and the first interlayer dielectric layer 313 include the same two elements.

In some embodiment, the first detective dielectric layer 312 includes an element that is different from the elements contained in the first passivation layer 311, and is a dielectric layer composed of silicon, oxygen and nitrogen. In the direction from the source electrode(S) to the drain electrode (D), each of the first passivation layer 311, the first detective dielectric layer 312, and the first interlayer dielectric layer 313 has two portions respectively located at two sides of the foot portion 210.

In some embodiments, a ratio of nitrogen to oxygen in the first detective dielectric layer 312 ranges from 1:3 to 1:2. After some experiments, it is found that when the ratio of nitrogen to oxygen in the first detective dielectric layer 312 ranges from 1:3 to 1:2, the capability of detecting an etching endpoint can be enhanced during the etching process of the passivation structure 3.

In some embodiments, the same two elements included in each of the first passivation layer 311, the first detective dielectric layer 312, and the first interlayer dielectric layer 313 are nitrogen and silicon. Since the layers of the passivation structure 3 include the same two elements, deposition of the passivation structure 3 may be simplified. Specifically, the first passivation layer 311 is deposited on the epitaxial structure 100 using PECVD, and in this embodiment, the thickness of the first passivation layer 311 is 100 Å. The first detective dielectric layer 312 is deposited on the first passivation layer 311 under 300° C. to 400° C. at a gas atmosphere including N2 and O2, has the thickness of 2 Å, and includes silicon oxynitride. In some embodiments, the first interlayer dielectric layer 313 is deposited on the first detective dielectric layer 312 using low-pressure CVD (LPCVD), has the thickness of 1500 Å, and includes silicon nitride. In this embodiment, a first etching method is performed for etching the first interlayer dielectric layer 313. Once the third element (i.e., oxygen) in the first detective dielectric layer 312 is detected, the first etching method is ceased and a second etching method is performed for etching the first detective dielectric layer 312 and the first passivation layer 311.

Quality of a gate recess of the group III-nitride transistor (e.g., the GaN HEMT) affects performance of the transistor, and a topography of the gate recess affects a property of a gate electrode of the transistor. In some embodiments, for a good passivation and dielectric effect, the first interlayer dielectric layer 313 is usually formed using LPCVD to have a relatively great density. However, LPCVD is usually performed under a relatively high temperature, which may adversely affect performance of the epitaxial structure 100 if the first interlayer dielectric layer 313 is directly formed thereon. In order to prevent said situation, the first passivation layer 311 that has the thickness smaller than 200 Å and that includes silicon nitride is firstly formed on the epitaxial structure 100, and the first detective dielectric layer 312 is formed thereon to generate a protective interface before the first interlayer dielectric layer 313 is formed.

The first detective dielectric layer 312 has the thickness ranging from 0.5 Å to 15 Å, which helps stress relief between the first passivation layer 311 and the epitaxial structure 100 and does not affect the connection between the layers of the passivation structure 3.

In the disclosure, the first detective dielectric layer 312 is used to effectively control a consistency of the topography of the gate recess in mass production of the semiconductor devices, and thereby the performance of the gate electrode 200 and the performance of the semiconductor device are improved. Furthermore, the elements contained in the first passivation layer 311 is the same as the elements contained in the first interlayer dielectric layer 313, and in this embodiment, the first passivation layer 311 and the first interlayer dielectric layer 313 both include silicon nitride, and the first detective dielectric layer 312 includes silicon oxynitride. Thus, the first passivation layer 311, the first detective dielectric layer 312 and the first interlayer dielectric layer 313 are deposited separately, such that the stresses, the thicknesses, etc. thereof can be controlled separately, and the performance of the semiconductor device can be further improved.

The gate electrode 200 of the semiconductor device is a T-shaped gate electrode, which has a better performance. A size of the foot portion 210 of the gate electrode 200 in a direction parallel to a thickness direction of the passivation structure 3 is the same as the thickness of the passivation structure 3, and the thickness thereof ranges from 500 Å to 5000 Å. In some embodiments, the thickness of the passivation structure 3 ranges from 800 Å to 1200 Å.

The larger the angle (∠1), the more consistent the gate length in mass production of the semiconductor devices, while the larger the angle (∠2), the more unfavorable the deposition of the gate metal material. When the angle (∠2) ranges from 30° to 60°, the gate metal material can be better deposited.

In some embodiments, the thickness of the passivation structure 3 is smaller than the thickness of the gate electrode 200. In some embodiments, the ratio of the thickness of the first passivation layer 311 to the thickness of the first interlayer dielectric layer 313 is not smaller than 1:5.

Referring to FIG. 4, a second embodiment of the semiconductor device is similar to the first embodiment, but the side wall of the passivation structure 3 has three wall portions 211, 212, 213 that are adjacent to the foot portion 210 of the gate electrode 200. The wall portions 212, 213 are adjacent to the first interlayer dielectric layer 313 and are inclined with respect to the imaginary plane by different angles (i.e., a junction of the wall portions 212, 213 is at a portion of the side wall that is adjacent to the first interlayer dielectric layer 313), and the wall portion 211 is adjacent to the first passivation layer 311. Since the density of the first interlayer dielectric layer 313 is relatively high, when the passivation structure 3 is etched, the consistency of topography of the wall portions 212, 213 can be well controlled in mass production of the semiconductor devices. Besides, when the different element in the first detective dielectric layer 312 is detected, the etching method is changed to etch the first passivation layer 311 for forming the wall portion 211, and the gate length may be precisely controlled to ensure the consistency of the performance of the gate electrode 200 in mass production of the semiconductor devices. In the second embodiment, the angle (∠3) between the wall portion 213 and the imaginary plane ranges from 70° to 90°, the angle (∠2) ranges from 30° to 60°, and the angle (∠1) ranges from 70° to 90°.

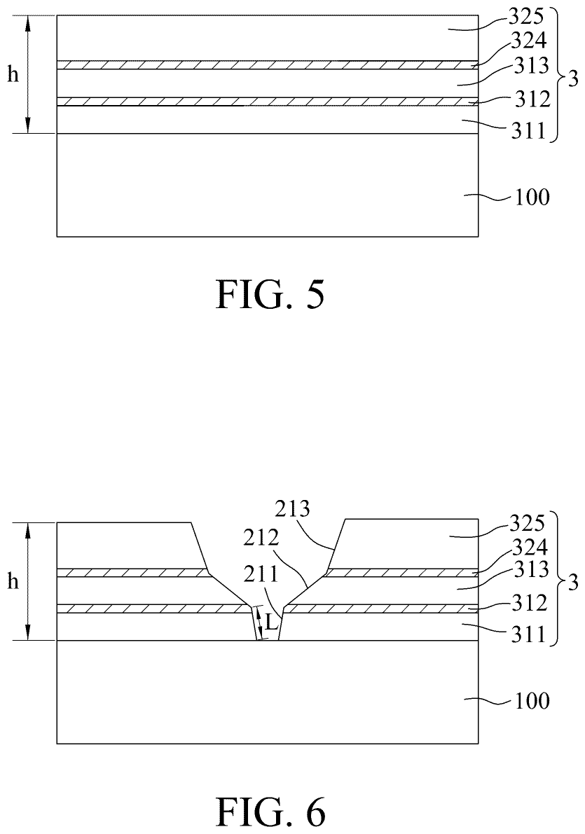

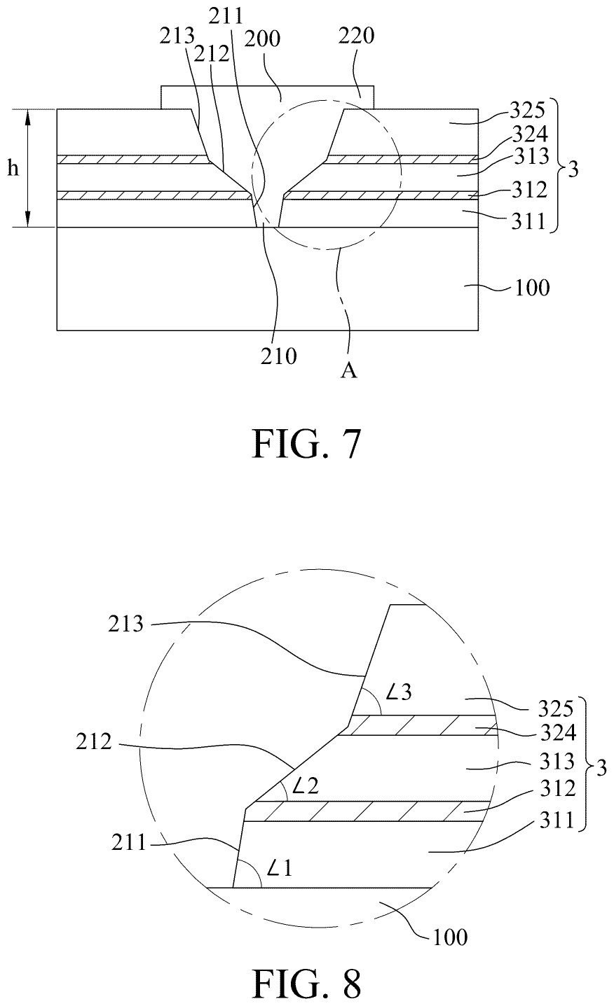

FIGS. 5 to 7 illustrate three intermediate stages for forming a third embodiment of the semiconductor device, respectively. FIG. 8 is a partially enlarged view of FIG. 7. The third embodiment is similar to the first embodiment and but for further improving the breakdown resistance of the semiconductor device. In the followings, only the differences between the first and third embodiments will be presented for the sake of brevity. In the third embodiment, the passivation structure 3 further includes a second detective dielectric layer 324 disposed on the first interlayer dielectric layer 313 and a second interlayer dielectric layer 325 disposed on the second detective dielectric layer 324, and the thicknesses of the first passivation layer 311, the first detective dielectric layer 312, the first interlayer dielectric layer 313, the second detective dielectric layer 324 and the second interlayer dielectric layer 325 are as follows.

In the third embodiment, the thickness (h) of the passivation structure 3 ranges from 500 Å to 5000 Å, and in some embodiments, the thickness (h) of the passivation structure 3 is 1000 Å. Due to the first detective dielectric layer 312 and the second detective dielectric layer 324 being included in the passivation structure 3, stress relief of the passivation structure 3 during the manufacturing process of the semiconductor device is improved. The thickness of the first detective dielectric layer 312 ranges from 0.5 Å to 15 Å, and a thickness of the second detective dielectric layer 324 ranges from 0.5 Å to 15 Å.

In some embodiments, when the ratio of the thickness of the first detective dielectric layer 312 to the thickness of the first interlayer dielectric layer 313 is smaller than 1:50, a ratio of the thickness of the second detective dielectric layer 324 to the thickness of the first interlayer dielectric layer 313 is smaller than 1:10, and a ratio of the thickness of the second detective dielectric layer 324 to a thickness of the second interlayer dielectric layer 325 is smaller than 1:50, effects of the stresses of the first detective dielectric layer 312 and the second detective dielectric layer 324 on the combined stress of the passivation structure 3 can be omitted. In some embodiments, a ratio of the thickness of the first detective dielectric layer 312 to the thickness of the first interlayer dielectric layer 313 is smaller than 1:10.

In some embodiments, the first passivation layer 311, the first interlayer dielectric layer 313 and the second interlayer dielectric layer 325 include the same two elements; that is, the first passivation layer 311 includes two elements that are the same as two of the elements contained in the first interlayer dielectric layer 313 and two of elements contained in the second interlayer dielectric layer 325. The second detective dielectric layer 324 includes an element that is different from the elements contained in the second interlayer dielectric layer 325; that is, the second detective dielectric layer 324 includes an element that the second interlayer dielectric layer 325 does not have. Besides, the second detective dielectric layer 324 includes an element that is the same as one of the elements contained in the second interlayer dielectric layer 325.

Each of said first passivation layer 311, the first interlayer dielectric layer 313, and the second interlayer dielectric layer 325 is composed of two elements, such as silicon and nitrogen, and each of the first detective dielectric layer 312 and the second detective dielectric layer 324 is composed of two elements, such as silicon and oxygen, which can simplify the deposition of the passivation structure 3. In this embodiment, the semiconductor device is exemplified as a GaN HEMT. The first passivation layer 311 is deposited on the epitaxial structure 100 using PECVD, includes or is made of silicon nitride, and has the thickness of 50 Å. The first detective dielectric layer 312 is deposited on the first passivation layer 311 using ALD, includes or is made of silicon oxynitride, and has the thickness of 5 Å. The first interlayer dielectric layer 313 is deposited on the first detective dielectric layer 312 using PECVD, includes or is made of silicon nitride, and has the thickness of 100 Å. The second detective dielectric layer 324 is deposited on the first interlayer dielectric layer 313 using ALD, includes or is made of silicon oxynitride, and has the thickness of 5 Å. The second interlayer dielectric layer 325 is deposited on the second detective dielectric layer 324 using PECVD, includes or is made of silicon nitride, and has the thickness of 1500 Å. In this case, the thickness of the passivation structure 3 is 1660 Å. In some embodiments, the thickness of the first passivation layer 311 ranges from 30 Å to 200 Å.

In the third embodiment, the first passivation layer 311, the first detective dielectric layer 312, the first interlayer dielectric layer 313, the second detective dielectric layer 324 and the second interlayer dielectric layer 325 are disposed adjacent to the foot portion 210 and between the head portion 220 and the epitaxial structure 100.

In some embodiments, each of the first detective dielectric layer 312 and the second detective dielectric layer 324 is composed of silicon, oxygen and nitrogen, is composed of silicon and oxygen, or is composed of aluminum and nitrogen.

In some embodiments, the thickness of the first detective dielectric layer 312 ranges from 2 Å to 5 Å, and the thickness of the second detective dielectric layer 324 ranges from 2 Å to 5 Å.

The first passivation layer 311, the first detective dielectric layer 312, the first interlayer dielectric layer 313, the second detective dielectric layer 324 and the second interlayer dielectric layer 325 include the same two elements, and in this embodiment, the same two elements are nitrogen and silicon. The second detective dielectric layer 324 includes an element that is different from the elements contained in the second interlayer dielectric layer 325 and the elements contained in the first interlayer dielectric layer 313.

In the third embodiment, each of the first passivation layer 311, the first interlayer dielectric layer 313, and the second interlayer dielectric layer 325 includes or is made of silicon nitride, and each of the first detective dielectric layer 312 and the second detective dielectric layer 324 includes or is made of silicon oxynitride, which can further improve the performance of the passivation structure 3 and avoid lattice mismatch between the layers of the passivation structure 3.

A method for preparing the third embodiment is as follows. The epitaxial structure 100 having a heterojunction is formed on a SiC substrate. The source electrode(S) and the drain electrode (D) are formed on an active region of the epitaxial structure 100 opposite to the SiC substrate, and are spaced apart from each other. The epitaxial structure 100 includes the channel layer and the barrier layer that is disposed on the channel layer. The channel layer is a binary group III-V compound semiconductor layer made of a group III-nitride material, and the barrier layer is a ternary group III-V compound semiconductor layer made of a group III-nitride material. In some embodiments, the source electrode(S) and the drain electrode (D) are formed on the barrier layer at the active region. For the passivation structure 3, the first passivation layer 311, the first detective dielectric layer 312, the first interlayer dielectric layer 313, the second detective dielectric layer 324 and the second interlayer dielectric layer 325 are sequentially formed on the epitaxial structure 100.

During the etching process of the passivation structure 3, an etching method for the second interlayer dielectric layer 325 (e.g., a dry etching method) is performed when the first element and the second element (such as silicon and nitrogen) are detected, the etching method for the first interlayer dielectric layer 313 (e.g., a dry etching method) is performed when the third element (such as oxygen) is detected, and the etching method for the first passivation layer 311 (e.g., a dry etching method) is performed when the third element is detected again, and the etching process will not end until the portion of the epitaxial structure 100 is exposed for disposing the gate electrode 200. That is, since the second detective dielectric layer 324 includes the element (i.e., the third element) that is different from the elements contained in the second interlayer dielectric layer 325, when the different element (i.e., the third element) is detected during the etching process of the passivation structure 3, it is acquired that a portion of the second detective dielectric layer 324 is exposed, and therefore the etching method is changed to the etching method for the first interlayer dielectric layer 313. Then, since the first detective dielectric layer 312 includes the element that is different from the elements contained in the first interlayer dielectric layer 313, when the different element (i.e., the third element) is detected during the etching process of the passivation structure 3 again, it is acquired that a portion of the first detective dielectric layer 312 is exposed, and therefore the etching method is changed to the etching method for the first passivation layer 311, and the etching process ends when the portion of the epitaxial structure 100 is exposed. Schottky metal is deposited on the portion of the epitaxial structure 100 that is exposed to form the gate electrode 200. The etching methods for the first interlayer dielectric layer 313 and the first passivation layer 311 are different in that, by controlling parameters, they have different processing conditions (e.g., the etching speed) in order to generate the wall portions 211, 212, 213 that are inclined with respect to the imaginary plane by different angles. By virtue of precisely controlling the processing conditions of the etching methods, the consistency of topography of the wall portions 211, 212, 213 is controlled in mass production of the semiconductor devices. Besides, the first passivation layer 311, the first detective dielectric layer 312, the first interlayer dielectric layer 313, the second detective dielectric layer 324 and the second interlayer dielectric layer 325 are deposited separately, such that the stresses, the thicknesses, etc. thereof can be controlled separately, and the performance of the semiconductor device can be further improved.

For each of the first detective dielectric layer 312 and the second detective dielectric layer 324, a ratio of nitrogen to oxygen therein ranges from 1:3 to 1:2. It is found that when the ratio of nitrogen to oxygen therein ranges from 1:3 to 1:2, the capability of detecting an etching endpoint can be enhanced during the etching process of the passivation structure 3.

In the third embodiment, the semiconductor device has three wall portions 211, 212, 213 that are adjacent to the foot portion 210 of the gate electrode 200. The wall portions 211, 212, 213 are respectively adjacent to the first passivation layer 311, the first interlayer dielectric layer 313 and the second interlayer dielectric layer 325. A junction of the wall portions 211, 212 is at the portion of the side wall that is adjacent to the first detective dielectric layer 312, and a junction of the wall portions 212, 213 is at a portion of the side wall that is adjacent to the second detective dielectric layer 324. The wall portions 211, 212, 213 are inclined with respect to the imaginary plane by different angles. The angle (∠3) between the wall portion 213 and the imaginary plane ranges from 70° to 90°, the angle (∠2) between the wall portion 212 and the imaginary plane ranges from 30° to 60°, and the angle (∠1) between the wall portion 211 and the imaginary plane ranges from 70° to 90°. Besides, a difference of the angle (∠3) and the angle (∠1) is not smaller than 10°. The angle (∠1) is greater than the angle (∠2) that is smaller than the angle (∠3). With the relationship among the angle (∠1), the angle (∠2) and the angle (∠3), it is beneficial to coverage of the gate electrode 200 in the gate recess and the gate parasitic capacitance. By virtue of the first detective dielectric layer 312 and the second detective dielectric layer 324, the capability of detecting the etching endpoint during the etching process of the passivation structure 3 is well controlled, the etching of the passivation structure 3 can be repeatedly performed in mass production of the semiconductor devices, which avoids differences in performance of the semiconductor devices.

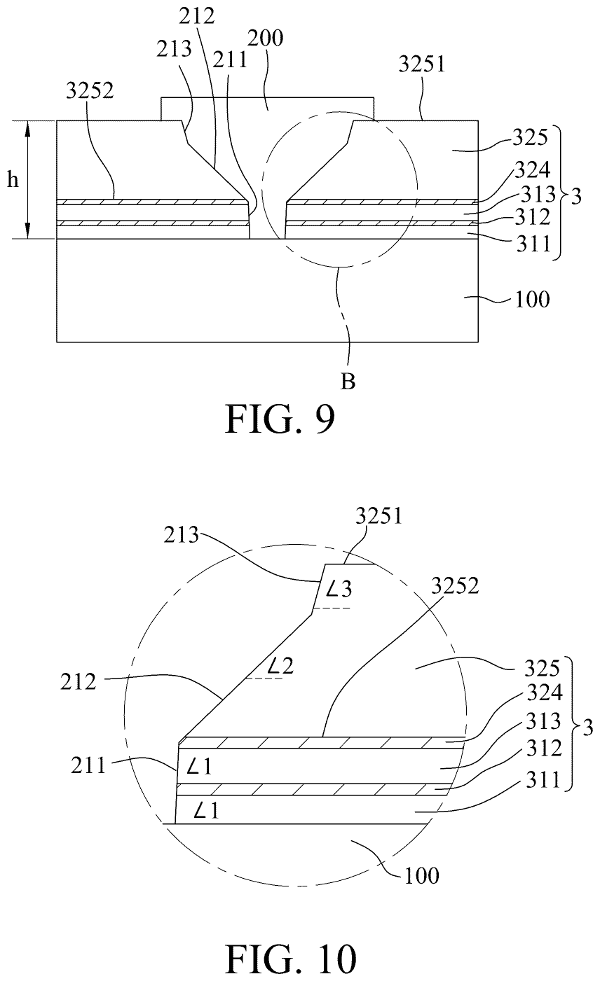

Referring to FIGS. 9 and 10, a fourth embodiment of the semiconductor device according to the disclosure is illustrated, and is similar to the third embodiment. Differences therebetween is as follows. The wall portion 211 is adjacent to the first passivation layer 311, the first detective dielectric layer 312 and the first interlayer dielectric layer 313, and the wall portions 212, 213 are adjacent to the second interlayer dielectric layer 325. A junction of the wall portions 211, 212 is at a portion of the side wall that is adjacent to the second detective dielectric layer 324, and a junction of the wall portions 212, 213 is at a portion of the side wall that is adjacent to the second interlayer dielectric layer 325. The angle (∠1) ranges from 80° to 90°. The second interlayer dielectric layer 325 includes a first surface 3251 that is in contact with the head portion 220 of the gate electrode 200, and a second surface 3252 that is opposite to the first surface 3521. The junction of the wall portions 212, 213 is proximate to the first surface 3251 and distal from the second surface 3252. The thickness of each of the first passivation layer 311 and the first interlayer dielectric layer 313 is smaller than 200 Å. In some embodiments, the thickness of the first interlayer dielectric layer 313 ranges from 30 Å to 100 Å, and the thickness of the first passivation layer 311 ranges from 30 Å to 100 Å. A ratio of the thickness of the second interlayer dielectric layer 325 to the thickness of the first passivation layer 311 is not smaller than 5:1, and a ratio of the thickness of the second interlayer dielectric layer 325 to the thickness of the first interlayer dielectric layer 313 is not smaller than 5:1. In an initial part of the etching process of the passivation structure 3, forming of the wall portions 212, 213 that are adjacent to the second interlayer dielectric layer 325 can be repeatedly performed in mass production of the semiconductor devices; however, the thickness of the second interlayer dielectric layer 325 is so large that the consistency of the gate recess may become worse in the following part of the etching process of the passivation structure 3 in mass production of the semiconductor devices. In order to prevent the situation, the thickness of the second interlayer dielectric layer 325 ranges from 800 Å to 1200 Å. Additionally, in some embodiments, the first passivation layer 311 is deposited by a method different from a method by which the first interlayer dielectric layer 313 is deposited; compared to a density of the first passivation layer 311, a density of the first interlayer dielectric layer 313 is higher, which ensures the structure of the passivation structure 3 to be more stable. By virtue of the first passivation layer 311 and the first detective dielectric layer 312, performance of the passivation structure 3 will not be affected during the deposition of the first interlayer dielectric layer 313, thereby ensuring the performance of the semiconductor device.

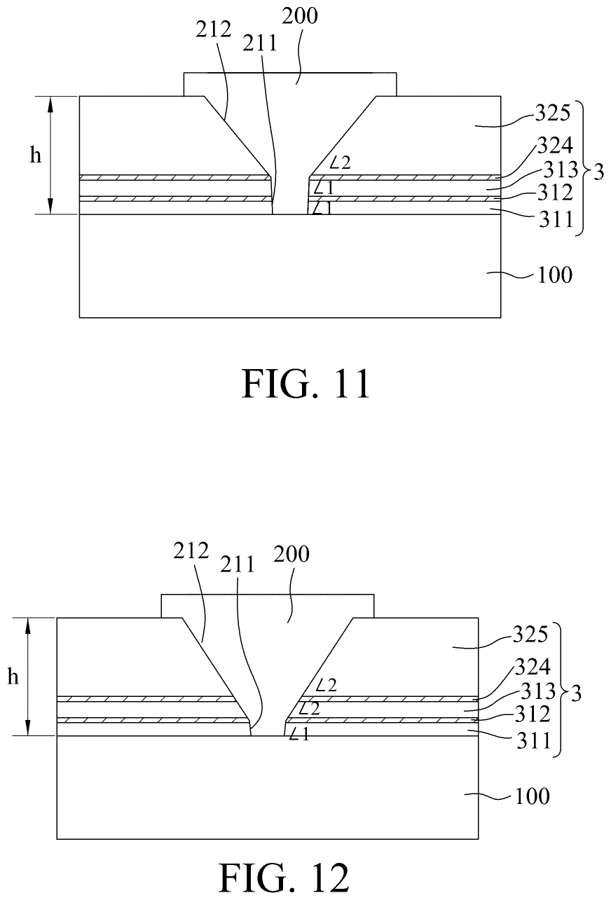

Referring to FIG. 11, a fifth embodiment of the semiconductor device according to the disclosure is illustrated, and is similar to the fourth embodiment. Differences therebetween lie in that the side wall of the passivation structure 3 has two wall portions 211, 212, and the junction of the wall portions 211, 212 is at the portion of the side wall that is adjacent to the second detective dielectric layer 324. The wall portion 212 is adjacent to the second interlayer dielectric layer 325, and the wall portion 211 is adjacent to the first passivation layer 311, the first detective dielectric layer 312 and the first interlayer dielectric layer 313. The angle (∠1) between the wall portion 211 and the imaginary plane is greater than the angle (∠2) between the wall portion 212 and the imaginary plane; the angle (∠1) ranges from 70° to 90° and the angle (∠2) ranges from 30° to 70°. In some embodiments, the angle (∠1) ranges from 75° to 85° and the angle (∠2) ranges from 45° to 60°.

FIG. 12 is a variation of the fifth embodiment. In the variation, the junction of the wall portions 211, 212 is at the portion of the side wall that is adjacent to the first detective dielectric layer 312. The wall portion 212 is adjacent to the second interlayer dielectric layer 325, the second detective dielectric layer 324 and the first interlayer dielectric layer 313, and the wall portion 211 is adjacent to the first passivation layer 311. The angle (∠1) is greater than the angle (∠2).

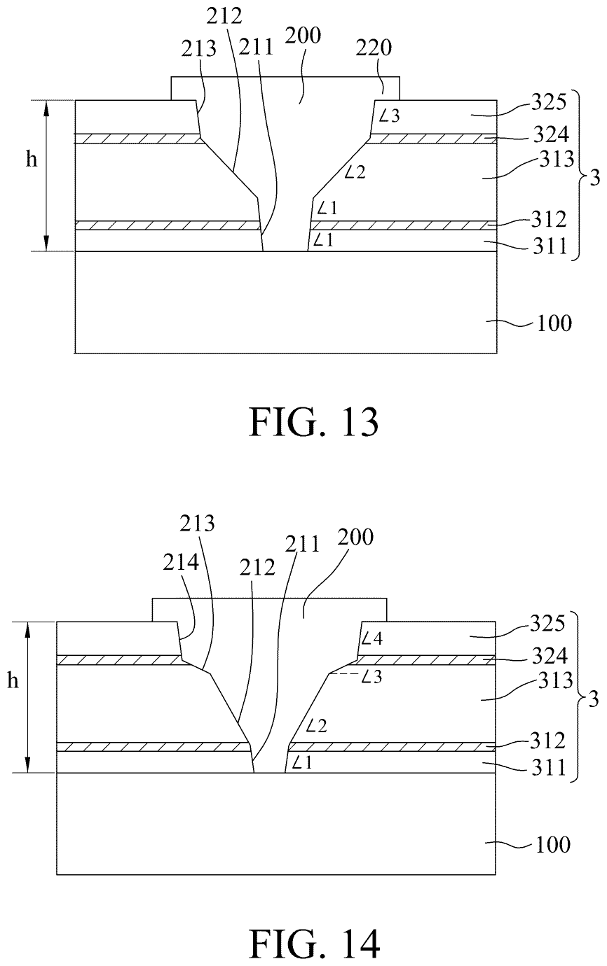

Referring to FIG. 13, a sixth embodiment of a semiconductor device according to the disclosure is illustrated. In this embodiment, the thickness of the first interlayer dielectric layer 313 is greater than the thickness of the second interlayer dielectric layer 325, such that it is relatively easy to form the wall portions 211, 212 at the first interlayer dielectric layer 313. The side wall of the passivation structure 3 has three wall portions 211, 212, 213. A junction of the wall portions 212, 213 is at a portion of the side wall that is adjacent to the second detective dielectric layer 324, and a junction of the wall portions 211, 212 is at a portion of the side wall that is adjacent to the first interlayer dielectric layer 313. The angle (∠1) between the wall portion 211 and the imaginary plane is greater than the angle (∠2) between the wall portion 212 and the imaginary plane, and the angle (∠3) between the wall portion 213 and the imaginary plane is greater than the angle (∠2). In some embodiments, a value of the angle (∠1) may be as large as possible and the angle (∠2) is smaller than the angle (∠1), which is beneficial to the gate length to be consistent in mass production of the semiconductor devices, and coverage of the gate electrode 200 in the gate recess. Besides, due to the angle (∠3) being greater than the angle (∠2) and the presence of the second detective dielectric layer 324, the endpoint can be effectively detected when the second interlayer dielectric layer 325 is being etched. Therefore, a topography of the wall portion 213 can be well controlled to form a T-shaped gate electrode 200 and a consistency of the electric field thereof is well controlled; in addition, due to the consistency of the angle (∠3) in mass production of the semiconductor device, a consistency of the head portion 220 of the gate electrode 200 is achieved.

FIG. 14 is a variation of the sixth embodiment. In the variation, the side wall of the passivation structure 3 has four wall portions 211, 212, 213, 214. A junction of the wall portions 213, 214 is at the portion of the side wall that is adjacent to the second detective dielectric layer 324, a junction of the wall portions 212, 213 is at the portion of the side wall that is adjacent to the first interlayer dielectric layer 313, and a junction of the wall portions 211, 212 is at the portion of the side wall that is adjacent to the first detective dielectric layer 312. Each of the angle (∠2) between the wall portion 212 and the imaginary plane and the angle (∠3) between the wall portion 213 and the imaginary plane is smaller than the angle (∠1) between the wall portion 211 and the imaginary plane, and/or is smaller than the angle (∠4) between the wall portion 214 and the imaginary plane. Compared to the embodiment in FIG. 13, the additional wall portion further ensures the consistency of the topography of the gate electrode 200 when the passivation structure 3 is etched in mass production of the semiconductor devices. Besides, since two of the wall portion 212, 213 are adjacent to the first interlayer dielectric layer 313, the coverage of the gate electrode 200 in the gate recess is further enhanced. In some embodiments, the angle (∠2) is greater than the angle (∠3), and the thickness of the second interlayer dielectric layer 325 is smaller than the thickness of the first interlayer dielectric layer 313. In some embodiments, the thickness of the first interlayer dielectric layer 313 ranges from 300 Å to 1000 Å, and the thickness of the second interlayer dielectric layer 325 is smaller than 1000 Å.

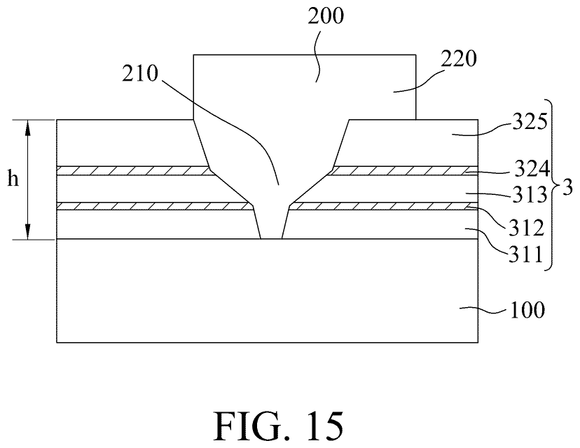

It should be noted that, the gate electrode 200 of the semiconductor device according to the disclosure is not limited to a T-shaped gate electrode. The gate electrode 200 may be Y-shaped or inverted-L shaped (see FIG. 15).

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A semiconductor device comprising:
an epitaxial structure having a group-III nitride material, and including a channel layer and a barrier layer that is disposed on said channel layer;
a source electrode disposed on said epitaxial structure;
a drain electrode disposed on said epitaxial structure and spaced apart from said source electrode;
a gate electrode disposed on said epitaxial structure and between said source electrode and said drain electrode, said gate electrode having a foot portion and a head portion; and
a passivation structure disposed on said epitaxial structure and including a first passivation layer that is disposed on said epitaxial structure, a first detective dielectric layer that is disposed on said first passivation layer, and a first interlayer dielectric layer that is disposed on said first detective dielectric layer;
wherein
said first detective dielectric layer includes an element that is different from elements contained in said first interlayer dielectric layer,
a ratio of a thickness of said first detective dielectric layer to a thickness of said first passivation layer is smaller than 1:10,
a ratio of said thickness of said first detective dielectric layer to a thickness of said first interlayer dielectric layer is smaller than 1:50,
a thickness of said passivation structure ranges from 500 Å to 5000 Å, and
said first passivation layer, said first detective dielectric layer and said first interlayer dielectric layer are disposed adjacent to a side surface of said foot portion of said gate electrode.

2. The semiconductor device as claimed in claim 1, wherein said thickness of said first passivation layer ranges from 30 Å to 200 Å, and said thickness of said first detective dielectric layer ranges from 0.5 Å to 15 Å.

3. The semiconductor device as claimed in claim 2, wherein said thickness of said first detective dielectric layer ranges from 2 Å to 5 Å.

4. The semiconductor device as claimed in claim 1, wherein said passivation structure has a side wall that is adjacent to said side surface of said foot portion and that has two wall portions inclined with respect to an imaginary plane parallel to said epitaxial structure by different angles.

5. The semiconductor device as claimed in claim 1, wherein said first detective dielectric layer is composed of nitrogen, silicon and oxygen.

6. The semiconductor device as claimed in claim 5, wherein said first passivation layer includes silicon nitri and said first detective dielectric layer includes silicon oxynitride.

7. The semiconductor device as claimed in claim 6, wherein said first interlayer dielectric layer includes silicon nitride.

8. The semiconductor device as claimed in claim 5, wherein a ratio of nitrogen to oxygen in said first detective dielectric layer ranges from 1:3 to 1:2.

9. The semiconductor device as claimed in claim 1, wherein a ratio of said thickness of said first passivation layer to said thickness of said first interlayer dielectric layer is smaller than 1:5.

10. A semiconductor device comprising:
an epitaxial structure that has a group III-nitride material and that includes a channel layer and a barrier layer disposed on said channel layer;
a source electrode that is disposed on said epitaxial structure;
a drain electrode that is disposed on said epitaxial structure and that is spaced apart from said source electrode;
a gate electrode that is disposed on said epitaxial structure, and between said source electrode and said drain electrode, said gate electrode having a foot portion and a head portion; and
a passivation structure that is disposed on said epitaxial structure and that includes a first passivation layer disposed on said epitaxial structure, a first detective dielectric layer disposed on said first passivation layer, a first interlayer dielectric layer disposed on said first detective dielectric layer, a second detective dielectric layer disposed on said first interlayer dielectric layer, and a second interlayer dielectric layer disposed on said second detective dielectric layer;
wherein
said first detective dielectric layer includes an element that is different from elements contained in said first interlayer dielectric layer,
said second detective dielectric layer includes an element that is different from elements contained in said second interlayer dielectric layer,
each of said first detective dielectric layer and said second detective dielectric layer is composed of silicon, oxygen and nitrogen, is composed of silicon and oxygen, or is composed of aluminum and nitrogen,
a thickness of said first detective dielectric layer ranges from 0.5 Å to 15 Å, and a thickness of said second detective dielectric layer ranges from 0.5 Å to 15 Å, and
said first passivation layer, said first detective dielectric layer, said first interlayer dielectric layer, said second detective dielectric layer and said second interlayer dielectric layer are disposed adjacent to a side surface of said foot portion and between said head portion and said epitaxial structure.

11. The semiconductor device as claimed in claim 10, wherein said first passivation layer, said first detective dielectric layer, said first interlayer dielectric layer, said second detective dielectric layer and said second interlayer dielectric layer include the same two elements.

12. The semiconductor device as claimed in claim 11, wherein said the same two elements are nitrogen and silicon.

13. The semiconductor device as claimed in claim 12, wherein each of said first passivation layer, said first interlayer dielectric layer, and said second interlayer dielectric layer includes silicon nitride, and each of said first detective dielectric layer and said second detective dielectric layer includes silicon oxynitride.

14. The semiconductor device as claimed in claim 12, wherein a ratio of nitrogen to oxygen in said first detective dielectric layer ranges from 1:3 to 1:2, and a ratio of nitrogen to oxygen in said second detective dielectric layer ranges from 1:3 to 1:2.

15. The semiconductor device as claimed in claim 10, wherein
said thickness of said first detective dielectric layer ranges from 2 Å to 5 Å, and said thickness of said second detective dielectric layer ranges from 2 Å to 5 Å,
said gate electrodehas a gate lengthranging from 500 Å to 7000 Å and greater than a thickness of said passivation structure; and an element is included in each of said first detective dielectric layer and said first interlayer dielectric layer, and an element is included in each of said second detective dielectric layer and said second interlayer dielectric layer.

16. The semiconductor device as claimed in claim 10, wherein said passivation structure has a side wall that is adjacent to said foot portion of said gate electrode and that has three wall portions inclined with respect to an imaginary plane parallel to said epitaxial structure by different angles.

17. The semiconductor device as claimed in claim 10, wherein said passivation structure has a side wall that is adjacent to said foot portion of said gate electrode and that has two wall portions inclined with respect to an imaginary plane parallel to said epitaxial structure by different angles.

18. A semiconductor device, comprising:
an epitaxial structure; and
a passivation structure that is disposed on said epitaxial structure and that includes a first passivation layer disposed on said epitaxial structure, a first detective dielectric layer disposed on said first passivation layer, a first interlayer dielectric layer disposed on said first detective dielectric layer, a second detective dielectric layer disposed on said first interlayer dielectric layer, and a second interlayer dielectric layer disposed on said second detective dielectric layer;
wherein
a ratio of a thickness of said first detective dielectric layer to a thickness of said first passivation layer is smaller than 1:10,
a ratio of said thickness of said first detective dielectric layer to a thickness of said first interlayer dielectric layer is smaller than 1:10,
a ratio of a thickness of said second detective dielectric layer to said thickness of said first interlayer dielectric layer is smaller than 1:10,
a ratio of said thickness of said second detective dielectric layer to a thickness of said second interlayer dielectric layer is smaller than 1:50,
said first detective dielectric layer includes an element that is different from elements contained in said first interlayer dielectric layer,
said second detective dielectric layer includes an element that is different from elements contained in said second interlayer dielectric layer,
said first passivation layer, said first detective dielectric layer, said first interlayer dielectric layer, said second detective dielectric layer and said second interlayer dielectric layer include the same two elements,
said thickness of said first passivation layer ranges from 30 Å to 200 Å,
a thickness of said passivation structure ranges from 500 Å to 5000 Å;
said thickness of said first detective dielectric layer ranges from 0.5 Å to 15 Å, and
said thickness of said second detective dielectric layer ranges from 0.5 Å to 15 Å.

19. The semiconductor device as claimed in claim 18, wherein each of said first detective dielectric layer and said second detective dielectric layer is composed of silicon, oxygen and nitrogen, is composed of silicon and oxygen, or is composed of aluminum and nitrogen, and each of said first passivation layer, said first interlayer dielectric layer and said second interlayer dielectric layer is composed of silicon and nitrogen.

20. The semiconductor device as claimed in claim 19, wherein each of said first detective dielectric layer and said second detective dielectric layer is composed of silicon and oxygen.
